(19) United States
(12) Patent Application Publication
(10) Pub. No.: US 2025/0052818 A1
(43) Pub. Date: Feb. 13, 2025

(54) SECONDARY BATTERY DIAGNOSTIC METHOD, SECONDARY BATTERY DIAGNOSTIC PROGRAM, AND SECONDARY BATTERY DIAGNOSTIC DEVICE

(71) Applicant: Maxell, Ltd., Otokuni-gun, Kyoto (JP)

(72) Inventors: Yuko Kishimi, Otokuni-gun (JP); Nobuaki Matsumoto, Otokuni-gun (JP)

(73) Assignee: Maxell, Ltd., Otokuni-gun, Kyoto (JP)

(21) Appl. No.: 18/794,074

(22) Filed: Aug. 5, 2024

Related U.S. Application Data
(63) Continuation-in-part of application No. PCT/JP2023/003516, filed on Feb. 3, 2023.
(63) Continuation-in-part of application No. PCT/JP2023/027999, filed on Jul. 31, 2023.

(30) Foreign Application Priority Data
Feb. 7, 2022 (JP) 2022-017035
Apr. 21, 2022 (JP) 2022-069863
Apr. 21, 2022 (JP) 2022-069870
Apr. 21, 2022 (JP) 2022-070009
Aug. 1, 2022 (JP) 2022-122502

(51) Int. Cl. G01R 31/367; G01R 31/392; H01M 10/0525; H01M 10/48

(52) U.S. Cl. CPC G01R 31/367; G01R 31/392; H01M 10/0525; H01M 10/48

(57) ABSTRACT

Provided is a secondary battery diagnostic method that can evaluate a remaining life of a secondary battery more accurately than in the related art without disassembly of the secondary battery. The secondary battery diagnostic method includes estimating characteristic parameters of a secondary battery to be diagnosed at a time of diagnosis (step S1), obtaining a relationship between an electrolyte diffusion coefficient and a discharge capacity (step S2), determining, on the basis of the relationship between the electrolyte diffusion coefficient and the discharge capacity, a threshold value Dth of the electrolyte diffusion coefficient (step S3), and obtaining a difference ΔD between the threshold value Dth and an electrolyte diffusion coefficient Dn at the time of diagnosis (step S4).

### TECHNICAL FIELD

The present invention relates to a secondary battery diagnostic method, a secondary battery diagnostic program, and a secondary battery diagnostic apparatus.

### BACKGROUND ART

A secondary battery such as a lithium ion battery gradually decreases in discharge capacity with repeated charging and discharging. Therefore, the secondary battery is preferably diagnosed at an appropriate time to evaluate a degree of deterioration thereof and determine whether reuse is possible or determine a replacement period. Further, to reuse the secondary battery after diagnosis, preferably the diagnosis is performed in a non-destructive manner.

JP 2017-97997 A describes a characteristic analysis method for a secondary battery in which a model equation, parameters of which are characteristic values of members constituting the battery, is used, and the characteristic values of the member are estimated by fitting a voltage value of the battery represented by the model equation with actual measurement data. In this characteristic analysis method, the actual measurement data used is obtained by applying a charge/discharge pattern to the battery under analysis, which includes an operation period consisting of either a constant current discharge period or a constant current charge period, followed by a rest period.

Further, the publication describes, as the characteristic values estimated by the fitting with the actual measurement data, a lithium ion diffusion coefficient in a positive electrode active material, a lithium ion diffusion coefficient in a negative electrode active material, a lithium ion diffusion coefficient in an electrolyte (electrolyte diffusion coefficient), an interface resistance in the positive electrode active material, an interface resistance in the negative electrode active material, a lithium ion salt concentration in the electrolyte, and the like.

### CITATION LIST

### Patent Literature

Patent Document 1: JP 2017-97997 A

### SUMMARY OF INVENTION

### Technical Problem

In the related art, the degree of deterioration of a secondary battery is evaluated on the basis of a magnitude of discharge capacity or a magnitude of internal resistance at the time of diagnosis. However, according to research conducted by the present inventors, it has been found that, even if the magnitudes of discharge capacity and the magnitudes of internal resistance at the time of diagnosis are substantially the same, the numbers of times that secondary batteries can be used thereafter are not necessarily substantially the same. Specifically, among secondary batteries having substantially the same magnitudes of discharge capacity and magnitudes of internal resistance at the time of diagnosis, there exist secondary batteries in which the discharge capacity drops sharply after a small number of charge/discharge cycles, secondary batteries in which the discharge capacity does not substantially drop even after charging/discharging, and the like. As a result, a remaining life of the secondary battery cannot be accurately evaluated by measuring only the magnitude of discharge capacity and the magnitude of internal resistance at the time of diagnosis.

The aforementioned JP 2017-97997 A describes a method for estimating characteristic values of members constituting a secondary battery without disassembly of the secondary battery. However, this publication does not describe a specific method for evaluating the remaining life of the secondary battery from these characteristic values.

An object of the present invention is to provide a secondary battery diagnostic method, a secondary battery diagnostic program, and a secondary battery diagnostic apparatus that can evaluate a remaining life of a secondary battery more accurately than in the related art without disassembly of the secondary battery.

### Solution to Problem

A secondary battery diagnostic method according to an embodiment of the present invention includes estimating, on the basis of data obtained by measuring load characteristics of a secondary battery to be diagnosed, characteristic parameters of the secondary battery to be diagnosed at a time of diagnosis by using a predetermined model equation, the characteristic parameters including an electrolyte diffusion coefficient Dn of the secondary battery to be diagnosed at the time of diagnosis; obtaining, on the basis of the model equation and the characteristic parameters estimated, a discharge capacity when an electrolyte diffusion coefficient is changed, and obtaining a relationship between the electrolyte diffusion coefficient and the discharge capacity; determining, on the basis of the relationship between the electrolyte diffusion coefficient and the discharge capacity, a threshold value Dth of the electrolyte diffusion coefficient; and obtaining a difference ΔD between the threshold value Dth and the electrolyte diffusion coefficient Dn at the time of diagnosis.

A secondary battery diagnostic program according to an embodiment of the present invention is a secondary battery diagnostic program for causing a computer to execute estimating, on the basis of data obtained by measuring load characteristics of a secondary battery to be diagnosed, characteristic parameters of the secondary battery to be diagnosed at a time of diagnosis by using a predetermined model equation, the characteristic parameters including an electrolyte diffusion coefficient Dn of the secondary battery to be diagnosed at the time of diagnosis; obtaining, on the basis of the model equation and the characteristic parameters estimated, a discharge capacity when an electrolyte diffusion coefficient is changed, and obtaining a relationship between the electrolyte diffusion coefficient and the discharge capacity; determining, on the basis of the relationship between the electrolyte diffusion coefficient and the discharge capacity, a threshold value Dth of the electrolyte diffusion coefficient; and obtaining a difference ΔD between the threshold value Dth and the electrolyte diffusion coefficient Dn at the time of diagnosis.

A secondary battery diagnostic method according to an embodiment of the present invention includes estimating, on the basis of data obtained by measuring load characteristics of a secondary battery to be diagnosed, characteristic parameters of the secondary battery to be diagnosed at a time of diagnosis by using a predetermined model equation, the characteristic parameters including an electrolyte diffusion coefficient Dn of the secondary battery to be diagnosed at the time of diagnosis; estimating, on the basis of input data, a threshold value Dth of the electrolyte diffusion coefficient of the secondary battery to be diagnosed by using a learned model, the input data being data including some of the characteristic parameters at the time of diagnosis; and obtaining a difference ΔD between the threshold value Dth and the electrolyte diffusion coefficient Dn at the time of diagnosis. For each of a plurality of secondary batteries for learning, the following process is performed: determining characteristic parameters of the secondary battery for learning; obtaining, on the basis of the model equation and the characteristic parameters of the secondary battery for learning, a discharge capacity when an electrolyte diffusion coefficient of the secondary battery for learning is changed, and obtaining a relationship between the electrolyte diffusion coefficient and the discharge capacity of the secondary battery for learning; and determining, on the basis of the relationship between the electrolyte diffusion coefficient and the discharge capacity of the secondary battery for learning, a threshold value of the electrolyte diffusion coefficient of the secondary battery for learning. The learned model is generated by machine learning utilizing teacher data obtained by using, as input data, data including some of the characteristic parameters of the secondary batteries for learning and, as output data, the threshold values of the electrolyte diffusion coefficients of the secondary batteries determined.

A secondary battery diagnostic program according to an embodiment of the present invention is a secondary battery diagnostic program for causing a computer to execute estimating, on the basis of data obtained by measuring load characteristics of a secondary battery to be diagnosed, characteristic parameters of the secondary battery to be diagnosed at a time of diagnosis by using a predetermined model equation, the characteristic parameters including an electrolyte diffusion coefficient Dn of the secondary battery to be diagnosed at the time of diagnosis; estimating, on the basis of input data, a threshold value Dth of the electrolyte diffusion coefficient of the secondary battery to be diagnosed by using a learned model, the input data being data including some of the characteristic parameters at the time of diagnosis; and obtaining a difference ΔD between the threshold value Dth and the electrolyte diffusion coefficient Dn at the time of diagnosis. For each of a plurality of secondary batteries for learning, the following process is performed: determining characteristic parameters of the secondary battery for learning; obtaining, on the basis of the model equation and the characteristic parameters of the secondary battery for learning, a discharge capacity when an electrolyte diffusion coefficient of the secondary battery for learning is changed, and obtaining a relationship between the electrolyte diffusion coefficient and the discharge capacity of the secondary battery for learning; and determining, on the basis of the relationship between the electrolyte diffusion coefficient and the discharge capacity of the secondary battery for learning, a threshold value of the electrolyte diffusion coefficient of the secondary battery for learning. The learned model is generated by machine learning utilizing teacher data obtained by using, as input data, data including some of the characteristic parameters of the secondary batteries for learning and, as output data, the threshold values determined for the electrolyte diffusion coefficients of the secondary batteries.

A secondary battery diagnostic apparatus according to an embodiment of the present invention includes a parameter estimation device configured to estimate, on the basis of data obtained by measuring load characteristics of a secondary battery to be diagnosed, characteristic parameters of the secondary battery to be diagnosed at a time of diagnosis by using a predetermined model equation, the characteristic parameters including an electrolyte diffusion coefficient Dn of the secondary battery to be diagnosed at the time of diagnosis; a threshold value estimation device configured to estimate, on the basis of input data, a threshold value Dth of the electrolyte diffusion coefficient of the secondary battery to be diagnosed by using a learned model, the input data being data including some of the characteristic parameters at the time of diagnosis; and a difference calculation device configured to obtain a difference ΔD between the threshold value Dth and the electrolyte diffusion coefficient Dn at the time of diagnosis. For each of a plurality of secondary batteries for learning, the following process is performed: determining characteristic parameters of the secondary battery for learning; obtaining, on the basis of the model equation and the characteristic parameters of the secondary battery for learning, a discharge capacity when an electrolyte diffusion coefficient of the secondary battery for learning is changed, and obtaining a relationship between the electrolyte diffusion coefficient and the discharge capacity of the secondary battery for learning; and determining, on the basis of the relationship between the electrolyte diffusion coefficient and the discharge capacity of the secondary battery for learning, a threshold value of the electrolyte diffusion coefficient of the secondary battery for learning. The learned model is generated by machine learning utilizing teacher data obtained by using, as input data, data including some of the characteristic parameters of the secondary batteries for learning and, as output data, the threshold values determined for the electrolyte diffusion coefficients of the secondary batteries.

A secondary battery diagnostic apparatus according to an embodiment of the present invention includes a parameter estimation device configured to estimate, on the basis of data obtained by measuring load characteristics of a secondary battery to be diagnosed, characteristic parameters of the secondary battery to be diagnosed at a time of diagnosis by using a predetermined model equation, the characteristic parameters including an electrolyte diffusion coefficient Dn of the secondary battery to be diagnosed at the time of diagnosis; a first data generation device configured to determine, for each of a plurality of secondary batteries for learning, characteristic parameters of the secondary battery for learning; a second data generation device configured to obtain, on the basis of the model equation and the characteristic parameters of the secondary battery for learning, a discharge capacity when an electrolyte diffusion coefficient of the secondary battery for learning is changed, and obtain a relationship between the electrolyte diffusion coefficient and the discharge capacity of the secondary battery for learning; a third data generation device configured to determine, on the basis of the relationship between the electrolyte diffusion coefficient and the discharge capacity of the secondary battery for learning, a threshold value of the electrolyte diffusion coefficient of the secondary battery for learning; a model generation device configured to generate a learned model by machine learning utilizing teacher data obtained by using, as input data, data including some of the characteristic parameters of the secondary batteries for learning and, as output data, the threshold values of the electrolyte diffusion coefficients of the secondary batteries determined; a threshold value estimation device configured to estimate, on the basis of input data, a threshold value Dth of the electrolyte diffusion coefficient of the secondary battery to be diagnosed by using the learned model, the input data being data including some of the characteristic parameters at the time of diagnosis; and a difference calculation device configured to obtain a difference ΔD between the threshold value Dth and the electrolyte diffusion coefficient Dn at the time of diagnosis.

### Advantageous Effects of Invention

According to the present invention, it is possible to evaluate a remaining life of a secondary battery more accurately than in the related art without disassembly of the secondary battery. Accordingly, for example, it is possible to efficiently use and replace a secondary battery provided in an electronic device.

### BRIEF DESCRIPTION OF DRAWINGS

FIG. 1 is a flowchart of a secondary battery diagnostic method according to a first embodiment of the present invention.

FIG. 2 is a flowchart illustrating an example of a more specific procedure of a process of estimating characteristic parameters.

FIG. 3 is a graph showing an example of a relationship between an electrolyte diffusion coefficient and a discharge capacity.

FIG. 4 is a graph showing an example of how to determine a threshold value Dth.

FIG. 5 is a flowchart illustrating a more specific procedure of a process of determining the threshold value Dth of the electrolyte diffusion coefficient in the secondary battery diagnostic method according to a second embodiment of the present invention.

FIG. 6 is a graph obtained by fitting the relationship between the electrolyte diffusion coefficient and the discharge capacity shown in FIG. 3 with equation (1).

FIG. 7 is a flowchart of the secondary battery diagnostic method according to a third embodiment of the present invention.

FIG. 8 is a flowchart of the secondary battery diagnostic method according to a fourth embodiment of the present invention.

FIG. 9 is a flowchart of the secondary battery diagnostic method according to a fifth embodiment of the present invention.

FIG. 10 is a flowchart illustrating an example of a method for creating teacher data.

FIG. 11 shows the relationship between ΔD obtained by diagnosis and the number of cycles at the onset of a sharp drop.

FIG. 12 is a graph showing a relationship between the number of cycles and the discharge capacity of two cells (cell No. 1 and cell No. 3) in which Li deposition occurred.

FIG. 13 is a graph showing the relationship between the number of cycles and the electrolyte diffusion coefficient.

FIG. 14 is a graph showing results of a cycle test of a deteriorated cell used for estimation in FIG. 13.

FIG. 15 is a graph obtained by adding a relationship between the number of cycles and the threshold value of the electrolyte diffusion coefficient to the graph in FIG. 13.

FIG. 16 is a chart illustrating a procedure of machine learning.

FIG. 17 is a scatter diagram obtained by plotting predicted values of the threshold value of the electrolyte diffusion coefficient on the vertical axis and plotting true values (values obtained by analysis) on the horizontal axis with respect to training data.

FIG. 18 is a scatter diagram obtained by plotting predicted values of the threshold value of the electrolyte diffusion coefficient on the vertical axis and plotting true values (values obtained by analysis) on the horizontal axis with respect to validation data.

FIG. 19 is a scatter diagram obtained by plotting predicted values of the threshold value of the electrolyte diffusion coefficient on the vertical axis and plotting true values (values obtained by analysis) on the horizontal axis with respect to training data.

FIG. 20 is a scatter diagram obtained by plotting predicted values of the threshold value of the electrolyte diffusion coefficient on the vertical axis and plotting true values (values obtained by analysis) on the horizontal axis with respect to validation data.

### DESCRIPTION OF EMBODIMENTS

The present inventors focused on an electrolyte diffusion coefficient when evaluating a remaining life of a secondary battery. In the course of cycle deterioration, a secondary battery approaches a state of so-called “liquid depletion” as an electrolyte amount and a salt concentration therein decrease. It is known that, at this time, the value of the electrolyte diffusion coefficient decreases. A value Dn of the electrolyte diffusion coefficient of the secondary battery at the time of diagnosis can be estimated in a non-destructive manner by using measurement data of load characteristics and a model equation well known in this field. Further, a relationship between the electrolyte diffusion coefficient and a discharge capacity can be obtained by simulation using the model equation described above.

A value Dth of the electrolyte diffusion coefficient when the secondary battery becomes unsuitable for reuse is determined from the relationship between the electrolyte diffusion coefficient and the discharge capacity, and a difference ΔD=Dn−Dth from the value Dn of the electrolyte diffusion coefficient at the time of diagnosis is then obtained. This ΔD can be used as an index of the remaining life of the secondary battery. That is, an evaluation can be made as follows: the larger the value of ΔD, the lower the likelihood early liquid depletion occurs, and the higher the likelihood the secondary battery can be used over a long period of time. Conversely, the smaller the value of ΔD, the higher the likelihood early liquid depletion occurs and the lower the likelihood the secondary battery can be used over a long period of time. A method for predicting a sharp drop in discharge capacity due to such liquid depletion has been nonexistent heretofore. By using this technique, it is possible to evaluate the remaining life of a secondary battery more accurately than in the related art.

### Method for Determining Threshold Value Dth of Electrolyte Diffusion Coefficient

The present inventors have further studied methods for determining the threshold value Dth of the electrolyte diffusion coefficient used in the above evaluation. Basically, the threshold value Dth can be determined as desired in accordance with the application of the secondary battery and the like. On the other hand, in terms of more reliably evaluating the reusable life, it is a reasonable approach to determine, as the threshold value Dth, the value of the electrolyte diffusion coefficient at an initial stage of onset of a sharp drop in discharge capacity, and intentionally secure a large margin.

The relationship between the electrolyte diffusion coefficient and the discharge capacity is not linear, but rather exhibits a curve in which the decrease in discharge capacity increases as the electrolyte diffusion coefficient decreases. The relationship between an electrolyte diffusion coefficient D and the discharge capacity can be accurately approximated by equation (1) below.

$$Discharge capacity = A max - B \times EXP ( Dh / D ) \qquad ( 1 )$$

Here, Amax (maximum capacity), B (decrease rate), and Dh (decrease coefficient) are parameters obtained by fitting the relationship between the electrolyte diffusion coefficient and the discharge capacity obtained by the simulation described above.

When the value of the electrolyte diffusion coefficient at the initial stage of onset of a sharp drop in discharge capacity is determined to be the threshold value Dth, the threshold value Dth may be set to a value of from 50% to 60% of Dh in equation (1) described above. While the electrolyte diffusion coefficient is in a range of from 50% to 60% of Dh, with reference to the absolute value of the discharge capacity, it can still be said that the discharge capacity is being sufficiently maintained. On the other hand, in view of the fact that the discharge capacity decreases exponentially thereafter, by defining the value of the electrolyte diffusion coefficient of this time point as the threshold value Dth, it is possible to more reliably evaluate the reusable life. Even in a case in which there is a measurement error in the data used at the time of diagnosis or a simulation error, for example, it is possible to more reliably evaluate the reusable life.

Further, a sharp drop in discharge capacity indicates that the diffusivity of the electrolyte inside the secondary battery is insufficient, and at least a portion of the active materials inside the electrodes is starting to become unable to contribute to reactions. When more than a certain level of active materials inside the electrodes can no longer contribute to reactions, the reaction is localized, increasing the likelihood of Li deposition. That is, it can be said that the time point of the onset of a sharp drop in discharge capacity is the time point at which the likelihood of Li deposition increases. Therefore, from the viewpoint of taking into consideration the likelihood of Li deposition as well, arguably the threshold value Dth is preferably determined to be a value of from 50% to 60% of Dh.

Relationship Between ΔD and Number of Cycles

The life of a secondary battery greatly varies depending on usage conditions (for example, discharge rate). Therefore, the evaluation of the remaining life by ΔD described above does not necessarily mean the prediction of a specific number of charge/discharge cycles until the battery becomes unsuitable for reuse.

However, the present inventors have found that, in a secondary battery that uses a general-purpose active material such as NCM, LCO, GC, or SiO, when the secondary battery undergoes cycle deterioration under certain conditions, the electrolyte diffusion coefficient decreases substantially linearly with respect to the number of cycles. Therefore, in a case in which it is assumed that the secondary battery is used under certain conditions, the number of cycles at which the difference ΔD described above becomes zero can be predicted on the basis of a relationship between the electrolyte diffusion coefficient and the number of cycles.

In the case of cycle deterioration, as steady deterioration, a decrease in discharge capacity following the root law occurs, making it necessary to anticipate the occurrence of both this decrease and the sharp drop due to a reduction in liquid diffusivity. Until now, there has been no method for predicting, in terms of the “number” of cycles, the “sharp drop” that deviates from the root law. By using this technique, it is possible to evaluate the remaining life of a secondary battery more accurately than in the related art.

The present inventors further analyzed a deterioration state of the secondary battery in more detail in order to improve the accuracy of the prediction.

The threshold value Dth of the electrolyte diffusion coefficient described above is determined on the basis of the relationship between the electrolyte diffusion coefficient and the discharge capacity acquired from the characteristic parameters at the time of diagnosis. In this case, a change in a characteristic parameter other than the electrolyte diffusion coefficient is incorporated into a change in the electrolyte diffusion coefficient, making it possible to evaluate the remaining life by one parameter (electrolyte diffusion coefficient). In this way as well, the remaining life of the secondary battery can be evaluated with high accuracy to a certain extent. However, in an actual secondary battery, characteristic parameters other than the electrolyte diffusion coefficient also change with cycle deterioration, resulting in the possibility of occurrence of deviation between the threshold value Dth obtained from the characteristic parameters at the time of diagnosis and the actual threshold value.

The present inventors measured load characteristics of secondary batteries that had undergone cycle charge/discharge tests under certain conditions at a plurality of time points with different numbers of cycles, and obtained the threshold value of the electrolyte diffusion coefficient from the data of the load characteristics in the same manner as described above. As a result, it was found that the threshold value of the electrolyte diffusion coefficient also changes substantially linearly with respect to the number of cycles as in the case of the electrolyte diffusion coefficient. Taking this into consideration, by predicting the time point at which the electrolyte diffusion coefficient falls below the threshold value, it is possible to obtain, with higher accuracy, the number of cycles at the onset of a sharp drop in discharge capacity.

In the method for evaluating the remaining life of a secondary battery described above, to determine the threshold value Dth, it is necessary to perform a simulation and obtain the relationship between the electrolyte diffusion coefficient and the discharge capacity for each secondary battery to be evaluated. This simulation requires a predetermined amount of time and necessitates proficiency in the software used for the simulation. Therefore, to facilitate simpler evaluation of the remaining life of the secondary battery, preferably the threshold value Dth can be determined without performing this simulation.

The present inventors determined the threshold value Dth by performing the simulation described above on a plurality of secondary batteries having different types of active materials in the positive and negative electrodes, different usage conditions, different degrees of deterioration, and the like. The present inventors further constructed an estimation model (learned model) by machine learning using, as input data (explanatory variables), characteristic parameters that can be relatively easily acquired among the characteristic parameters of a secondary battery and, as output data (objective variable), the threshold value Dth determined, and succeeded in using this estimation model to estimate the threshold value Dth of a secondary battery having an unknown threshold value Dth. At this time, it was found that including the discharge capacity and the electrolyte conductivity of the secondary battery in the input data can improve the accuracy of the estimation.

The present invention has been completed on the basis of the above findings. Hereinafter, embodiments of the present invention will be described in detail with reference to the drawings.

### Secondary Battery Diagnostic Method

In the following description, first, a method for determining the threshold value Dth and ΔD without using an estimation model based on machine learning (hereinafter referred to as a “learned model”) will be described (first to fourth embodiments). Subsequently, a method for determining the threshold value Dth and ΔD by using the learned model will be described (fifth embodiment). In addition, a method for generating a learned model (learning method) will be described.

### First Embodiment

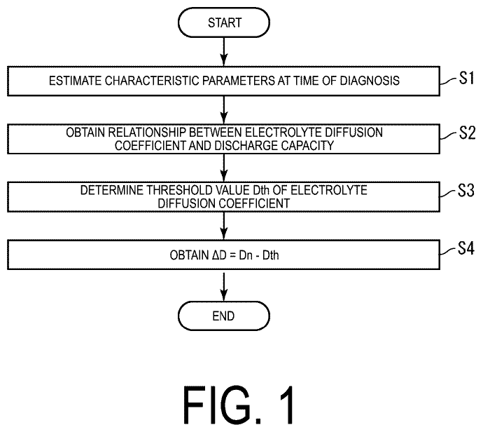

FIG. 1 is a flowchart of a secondary battery diagnostic method according to a first embodiment of the present invention. This diagnostic method includes a process of estimating characteristic parameters of a secondary battery to be diagnosed (hereinafter “target battery”) at a time of diagnosis (step S1), a process of obtaining the relationship between the electrolyte diffusion coefficient and the discharge capacity (step S2), a process of determining the threshold value Dth of the electrolyte diffusion coefficient (step S3), and a process of obtaining the difference ΔD between the threshold value Dth and the electrolyte diffusion coefficient Dn at the time of diagnosis (step S4). Hereinafter, each process will be described in detail.

### Process of Estimating Characteristic Parameters

Characteristic parameters of the target battery at the time of diagnosis are estimated (step S1). More specifically, on the basis of the data obtained by measuring the load characteristics of the target battery, the characteristic parameters of the target battery at the time of diagnosis, including the electrolyte diffusion coefficient Dn of the target battery at the time of diagnosis, are estimated by using a predetermined model equation.

In this process, characteristic parameters of the target battery at the time of diagnosis are estimated by fitting the data obtained by measuring the load characteristics of the target battery by using a predetermined model equation. This analysis (simulation) can be performed by a computer program that can perform fluid analysis, and can be performed by, for example, the software Battery Design Studio available from Siemens AG.

The model equation used can be an equation well known in this field. As the model equation, for example, the equation described in Marc Doyle et al., “Modeling of Galvanostatic Charge and Discharge of the Lithium/Polymer/Insertion Cell,” J. Electrochem. Soc., Vol. 140, No. 6, June (1993) can be used.

The target battery is, for example, a lithium ion battery.

The data obtained by measuring the load characteristics of the target battery is, for example, a discharge curve obtained by measuring the target battery at a plurality of discharge rates. This data preferably includes a discharge curve obtained by measurement at an extremely low discharge rate (0.02 C, for example). Further, this data preferably includes a discharge curve obtained by measurement at a discharge rate of 1 C or higher. This data preferably includes a discharge curve obtained by measurement at discharge rates of three or more levels, and more preferably includes a discharge curve obtained by measurement at discharge rates of four or more levels. The data obtained by measuring the load characteristics of the target battery may be a charge curve obtained by measuring the target battery at a plurality of charge rates.

The characteristic parameters estimated in this process (characteristic parameters of the target battery at the time of diagnosis) include at least the electrolyte diffusion coefficient Dn of the target battery at the time of diagnosis. The characteristic parameters can include, for example, a solid-phase diffusion coefficient of positive and negative electrode active materials and an electrolyte conductivity. Other specific examples of the characteristic parameters will be described below.

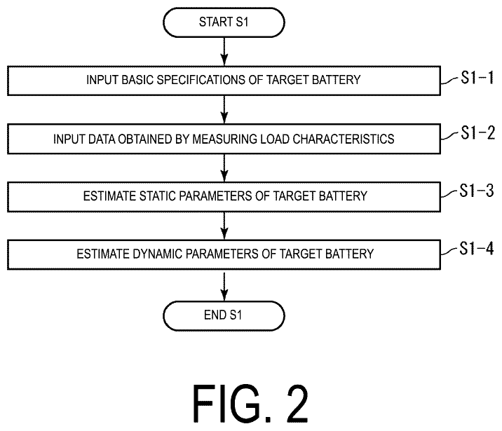

FIG. 2 is a flowchart illustrating an example of a more specific procedure of the process of estimating characteristic parameters (step S1). In this example, the process of estimating the characteristic parameters (step S1) includes a process of inputting basic specifications of the target battery (step S1-1), a process of inputting data obtained by measuring load characteristics of the target battery (step S1-2), a process of estimating static parameters of the target battery (step S1-3), and a process of estimating dynamic parameters of the target battery (step S1-4).

Basic specifications of the secondary battery to be diagnosed are input to the analysis software (step S1-1). The basic specifications input can include, but are not limited to, for example, the following.
Electrode compositions of positive and negative electrodes (constituent materials, content ratios, particle sizes, and the like)
Electrode thicknesses, densities, and tortuosities (approximately 1.5 in many cases) of positive and negative electrodes
Materials, thicknesses, and electrical conductivities of positive and negative electrode current-collecting foils
Thickness and porosity of separator
Composition of electrolyte (constituent materials, content ratios)
Thermal conductivities and heat capacities of the constituent materials (basic physical property values specific to the materials)
Electrode area

With the diagnosis being basically performed non-destructively, accurate composition information of the electrolyte at the time of diagnosis cannot be obtained. Therefore, general information of the secondary battery to be diagnosed (or standard information of a new battery) is obtained and input as parameters. Although some values need to be input when the simulation is actually performed, the composition of the electrolyte does not significantly affect the result of the simulation. In the diagnostic method of the present embodiment, the role of the electrolyte composition information is only for reference purposes.

Although the densities of the positive and negative electrodes are also expected to change due to expansion from initial states, accurate values at the time of diagnosis cannot be measured. Therefore, an initial value (standard value or the like) or a value predicted from the initial value is input. If the value is completely unknown, a typical value may be input. If necessary, fine adjustment may be performed in step S1-4.

The data obtained by measuring the load characteristics of the target battery is input to the analysis software (step S1-2). The data obtained by measuring the load characteristics of the target battery is, as described above, a discharge curve obtained by measuring the target battery at a plurality of discharge rates, or the like. The “data obtained by measuring the load characteristics of the target battery” is hereinafter also referred to as “actual measurement data”.

The static parameters of the target battery are estimated from the actual measurement data and the model equation (step S1-3). For example, the static parameters of the target battery are adjusted so as to match a shape of the discharge curve obtained by measurement at an extremely low discharge rate. The discharge curve obtained by measurement at an extremely low discharge rate (0.02 C, for example) can be considered to approximately coincide with a voltage curve when no load is connected (open-circuit voltage curve (OCV)). The static parameters can include, but are not limited to, for example, the following.
Capacities per unit weight of positive and negative electrode active materials (battery after use decreases in discharge capacity)
Respective utilization rates of positive and negative electrode active materials (not all regions are mutually used)
Maximum voltage and minimum voltage of target battery usage range

The dynamic parameters of the target battery are estimated from the actual measurement data and the model equation (step S1-4). For example, a simulation is performed in which the target battery is discharged at a current value equivalent to that of the measurement conditions of actual measurement data, and the dynamic parameters are adjusted while comparing the data obtained by this simulation result and the actual measurement data such that the two coincide. This simulation can be performed using, for example, the discharge curve prediction of Battery Design Studio described above. The dynamic parameters may include, but are not limited to, for example, the following.
Electrolyte conductivity
Electrolyte diffusion coefficient
Solid phase diffusion coefficients of positive and negative electrode active materials
Heat capacity of target battery

The ambient temperature at the time of the simulation is preferably set so as to coincide with the ambient temperature at the time of actual measurement data acquisition. In the case of a medium or larger sized product battery, particularly, a product battery assumed to be used at a high rate, preferably the influence of heat generation is taken into consideration. To achieve this, preferably measurements are performed at least at 1 C and fitting is conducted with the actual measurement data affected by heat generation. On the other hand, as long as the target battery is a small cell for a desk test or the like, the influence of heat generation need not be considered.

Through the above processes, it is possible to estimate the characteristic parameters of the target battery at the time of diagnosis, including the electrolyte diffusion coefficient Dn of the target battery at the time of diagnosis.

Process of Obtaining Relationship between Electrolyte Diffusion Coefficient and Discharge Capacity

On the basis of the model equation used in step S1 and the characteristic parameters estimated in step S1, the relationship between the electrolyte diffusion coefficient and the discharge capacity is obtained (step S2). More specifically, the discharge capacity is obtained by performing a discharge simulation while changing only the electrolyte diffusion coefficient among the characteristic parameters estimated in step S1 and keeping the other characteristic parameters constant. A discharge rate and an ambient temperature at the time of the discharge simulation are preferably set in accordance with the reuse application. For example, if the target battery is expected to be used in the application at an average rate of about 1 C, then the discharge rate used when obtaining the relationship between the electrolyte diffusion coefficient and the discharge capacity is also 1 C. Since it is difficult to precisely match all environmental conditions, simulations may be performed using average values.

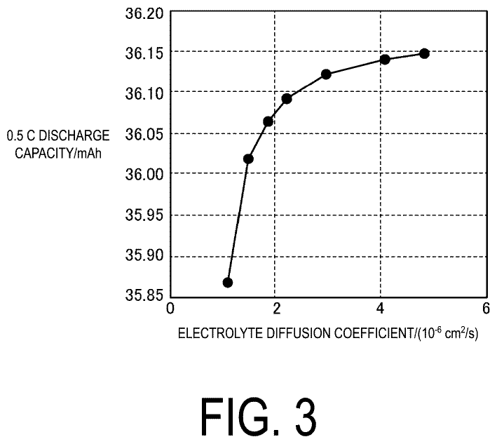

FIG. 3 is a graph showing an example of a relationship between the electrolyte diffusion coefficient and the discharge capacity. In this example, the discharge capacity with the ambient temperature set to 45° C. and the discharge rate set to 0.5 C was obtained for each case in which the electrolyte diffusion coefficient was 4.8×10⁻⁶, 4.0×10⁻⁶, 2.95×10⁻⁶, 1.85×10⁻⁶, 1.48×10⁻⁶, and 1.1×10⁻⁶ cm²/s.

As shown in this example, generally, the smaller the electrolyte diffusion coefficient, the smaller the discharge capacity. Further, the relationship between the electrolyte diffusion coefficient and the discharge capacity is not linear, but rather has a tendency to exhibit a curve such that the decrease in discharge capacity increases as the electrolyte diffusion coefficient decreases.

### Process of Determining Threshold Value Dth of Electrolyte Diffusion Coefficient

On the basis of the relationship between the electrolyte diffusion coefficient and the discharge capacity obtained in step S2, the threshold value Dth of the electrolyte diffusion coefficient is determined (step S3). More specifically, with reference to the relationship between the electrolyte diffusion coefficient and the discharge capacity obtained in step S2, the value of the electrolyte diffusion coefficient when the target battery becomes unsuitable for reuse is determined to be the threshold value Dth. A criterion for determining that the target battery is “not suitable for reuse” differs according to the intended reuse application of the target battery. Therefore, the criterion for determining that the target battery is “not suitable for reuse” is set in accordance with the application.

For example, when the discharge capacity becomes equal to or less than a predetermined permissible value, the determination may be made that the battery is not suitable for reuse. In this case, the electrolyte diffusion coefficient when the discharge capacity becomes equal to or less than the predetermined permissible value is determined to be the threshold value Dth. For example, in the example of FIG. 3, in a case in which the permissible value of the discharge capacity is 36.02 mAh, the threshold value Dth is 1.40×10⁻⁶ cm²/s.

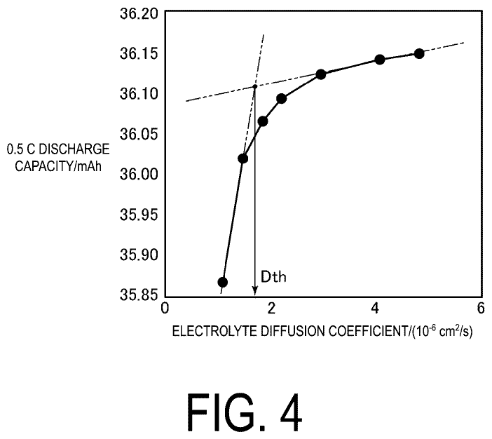

Alternatively, at the onset of a sharp drop in discharge capacity, the determination may be made that the battery is not suitable for reuse. In this case, the electrolyte diffusion coefficient at the onset of a sharp drop in discharge capacity is determined to be the threshold value Dth. For example, the electrolyte diffusion coefficient when a slope of the discharge capacity is equal to or greater than a predetermined magnitude may be set as the threshold value Dth. Further, as shown in FIG. 4, a point at which tangents of each curve before and after the onset of a sharp drop in discharge capacity intersect may be set as the threshold value Dth.

Process of Obtaining Difference ΔD between Threshold Value Dth and Electrolyte Diffusion Coefficient Dn at Time of Diagnosis A difference ΔD between the threshold value Dth determined in step S3 and the electrolyte diffusion coefficient Dn at the time of diagnosis estimated in step S1 is obtained (step S4). For example, if Dn=2.22×10⁻⁶ cm²/s and Dth=1.40×10⁻⁶ cm²/s, then ΔD=Dn−Dth=0.82×10⁻⁶ cm²/s.

This ΔD can be used as an index for the remaining life of the target battery. That is, the target battery can be evaluated as follows: the larger the value of ΔD, the higher the likelihood the target battery can be used for a long period of time, and the smaller the value of ΔD, the lower the likelihood the target battery can be used for a long period of time. Even if the discharge capacities at the time of diagnosis are about the same, ΔD may be different. By using ΔD, it is possible to more accurately evaluate the remaining life of the target battery as compared with known methods in which the remaining life is evaluated on the basis of the magnitude of the discharge capacity at the time of diagnosis.

As described above, the life of the secondary battery greatly varies depending on usage conditions, and thus “accurate evaluation of the remaining life” does not necessarily mean prediction of a specific number of charge/discharge cycles until unsuitable for reuse. However, if it is assumed that the target battery is continuously used under certain conditions, it is also possible to predict the remaining life (number of charge/discharge cycles) of the target battery from ΔD. For example, a relationship between ΔD and the remaining life may be measured in advance, and the remaining life of the target battery may be predicted on the basis of this relationship between ΔD and the remaining life.

### Second Embodiment

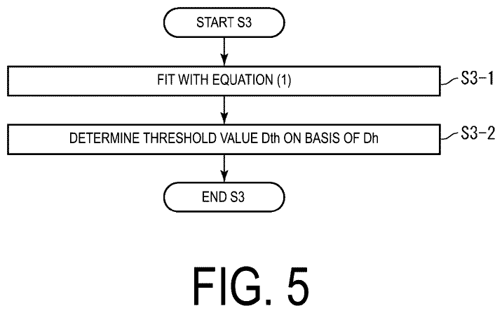

The secondary battery diagnostic method according to a second embodiment of the present invention differs from that of the first embodiment in the process of determining the threshold value Dth of the electrolyte diffusion coefficient (step S3). FIG. 5 is a flowchart illustrating a more specific procedure of the process of determining the threshold value Dth of the electrolyte diffusion coefficient (step S3) in the secondary battery diagnostic method according to the present embodiment. In the present embodiment, the process of determining the threshold value Dth of the electrolyte diffusion coefficient (step S3) includes a process of obtaining Amax, B, and Dh by fitting the relationship between the electrolyte diffusion coefficient D and the discharge capacity with equation (1) below (step S3-1), and a process of determining the threshold value Dth on the basis of Dh (step S3-2).

$$Discharge capacity = A max - B \times EXP ( Dh / D ) \qquad ( 1 )$$

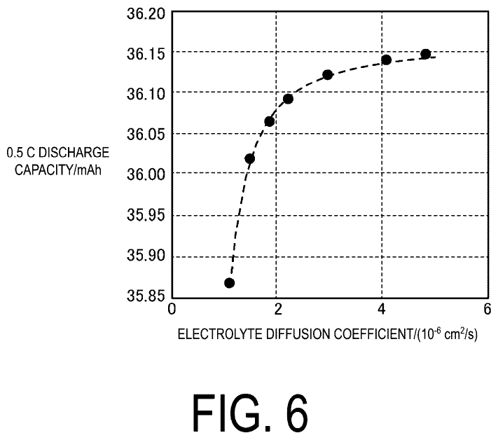

Amax, B, and Dh are obtained by fitting the relationship between the electrolyte diffusion coefficient D and the discharge capacity obtained in step S2 with equation (1) described above (step S3-1). FIG. 6 is a graph obtained by fitting the relationship between the electrolyte diffusion coefficient and the discharge capacity shown in FIG. 3 with equation (1). The dashed line in FIG. 6 represents the discharge capacity calculated by equation (1). In this example, Amax=36.2 mAh, B=0.034 mAh, and Dh=2.51×10⁻⁶ cm²/s. As shown in FIG. 6, the relationship between the electrolyte diffusion coefficient D and the discharge capacity can be accurately approximated by equation (1).

On the basis of Dh obtained in step S3-1, the threshold value Dth is determined (step S3-2). In equation (1) described above, Dh is a parameter characterizing the value of the electrolyte diffusion coefficient at the onset of a sharp drop in discharge capacity, and it is rational to determine the threshold value Dth by using Dh as reference.

Preferably, the threshold value Dth is determined to be to a value of from 50 to 60% of Dh.

For example, in the example of FIG. 6, in a case in which the threshold value Dth is set to a value of 56% of Dh (=2.51×10⁻⁶ cm²/s), the threshold value Dth is 1.40×10⁻⁶ cm²/s. The discharge capacity when the electrolyte diffusion coefficient is 1.40×10⁻⁶ cm²/s is estimated to be approximately 36.0 mAh from equation (1). This value represents a decrease within 1% from Amax (=36.2 mAh), and looking at the absolute value of the discharge capacity, it still can be said that the discharge capacity is being maintained. On the other hand, in view of the fact that the discharge capacity decreases exponentially thereafter, by defining the value of the electrolyte diffusion coefficient of this time point as the threshold value Dth, it is possible to more reliably evaluate the reusable life. Even in a case in which there is a measurement error in the data used at the time of diagnosis or a simulation error, for example, it is possible to more reliably evaluate the reusable life.

Further, a sharp drop in discharge capacity indicates that the diffusivity of the electrolyte inside the secondary battery is insufficient, and at least a portion of the active materials inside the electrodes is starting to become unable to contribute to reactions. When more than a certain level of active materials inside the electrodes can no longer contribute to reactions, the reaction is localized, increasing the likelihood of Li deposition. That is, it can be said that the time point of the onset of a sharp drop in discharge capacity is the time point at which the likelihood of Li deposition increases. Therefore, from the viewpoint of taking into consideration the likelihood of Li deposition as well, arguably the threshold value Dth is preferably determined to be a value of from 50% to 60% of Dh.

The larger the threshold value Dth, the shorter the remaining life of the target battery is evaluated to be. Therefore, if the threshold value Dth is set to a large value, the likelihood of overestimating the remaining life decreases, but the likelihood of underestimating the remaining life increases. On the other hand, if the threshold value Dth is set to a small value, the likelihood of underestimating the remaining life decreases, but the likelihood of overestimating the remaining life increases. The threshold value Dth is more preferably a value of from 54% to 58% of Dh.

### Third Embodiment

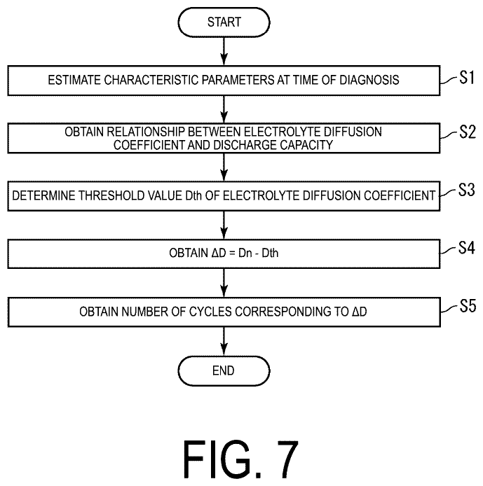

FIG. 7 is a flowchart of the secondary battery diagnostic method according to a third embodiment of the present invention. In addition to the processes included in the secondary battery diagnostic method according to the first embodiment (FIG. 1), this diagnostic method further includes a process of obtaining, on the basis of the relationship between the number of cycles and the electrolyte diffusion coefficient acquired in advance, the number of cycles corresponding to the difference ΔD (step S5).

### Process of Obtaining Number of Cycles Corresponding to Difference ΔD

The number of cycles corresponding to the difference ΔD is obtained on the basis of the relationship between the number of cycles and the electrolyte diffusion coefficient acquired in advance (step S5). As described above, the life of the secondary battery greatly varies depending on usage conditions, and thus the evaluation of the remaining life by the difference ΔD does not necessarily mean prediction of a specific number of charge/discharge cycles until the secondary battery becomes unsuitable for reuse. On the other hand, it has been experimentally revealed that, in a case in which the secondary battery undergoes cycle deterioration under certain conditions, the electrolyte diffusion coefficient decreases substantially linearly with respect to the number of cycles. Therefore, in a case in which it is assumed that the target battery is used under certain conditions, the relationship between the number of cycles and the electrolyte diffusion coefficient is acquired in advance, and the number of cycles described above until the difference ΔD becomes zero can be predicted on the basis of the relationship between the number of cycles and the electrolyte diffusion coefficient.

The relationship between the number of cycles and the electrolyte diffusion coefficient can be acquired, for example, as follows.

A charge/discharge cycle test is conducted on a secondary battery of the same type as that of the target battery under certain conditions to deteriorate this secondary battery. Here, a “secondary battery of the same type as that of the target battery” means a secondary battery in which the materials and shapes of the positive and negative electrodes, the type and amount of the electrolyte, and the like are equivalent to those of the target battery. For example, when the target battery is a product battery, a “secondary battery of the same type as that of the target battery” means a secondary battery or the like having the same model number. Hereinafter, this “secondary battery of the same type as that of the target battery” is referred to as a “secondary battery for measurement.”

The discharge rate, the ambient temperature, and the like in the charge/discharge cycle test are preferably set in accordance with the reuse application of the target battery. For example, if the target battery is expected to be used in the application at around 1C on average, then the discharge rate used during the charge/discharge cycle test is also 1C. Since it is difficult to precisely match all environmental conditions, the charge/discharge cycle test may be conducted using average values.

With the relationship between the number of cycles and the electrolyte diffusion coefficient being linear, the charge/discharge cycle test does not need to be repeated until the secondary battery for measurement is sufficiently deteriorated, and need only be conducted until the number of cycles reaches an appropriate number.

The load characteristics of the secondary battery for measurement are measured at two or more time points having different numbers of cycles, and the characteristic parameters of the secondary battery for measurement at each time point are estimated from the data of the load characteristics. The characteristic parameters can be estimated in the same manner as in the process of estimating the characteristic parameters of the target battery (step S1).

As described above, in a case in which the secondary battery undergoes cycle deterioration under certain conditions, the electrolyte diffusion coefficient decreases substantially linearly with respect to the number of cycles. Therefore, if the electrolyte diffusion coefficients at at least two time points are known, the relationship between the number of cycles and the electrolyte diffusion coefficient can be acquired. For example, given D1 as the value of the electrolyte diffusion coefficient when the number of cycles is n1 and D2 as the value of the electrolyte diffusion coefficient when the number of cycles is n2, a slope k_{D} of the electrolyte diffusion coefficient with respect to the number of cycles can be obtained from k_{D}=(D2−D1)/(n2−n1). Needless to say, the electrolyte diffusion coefficient may be estimated at three or more time points to obtain the slope k_{D}, thereby further reducing errors.

Note that, when the characteristic parameters at second and subsequent points are estimated, preferably, fitting is performed by changing only the discharge capacity, the electrolyte diffusion coefficient, and the electrolyte conductivity among the characteristic parameters estimated at the first point and fixing the other characteristic parameters to the characteristic parameters estimated at the first point. When estimating the characteristic parameters of second and subsequent points, the fitting may be performed by changing all characteristic parameters. However, when the fitting is performed by a person other than a skilled technician, the fitting may become inaccurate with the number of parameters, and the relationship between the number of cycles and the electrolyte diffusion coefficient may become inaccurate.

The relationship between the number of cycles and the electrolyte diffusion coefficient may be obtained by conducting a charge/discharge cycle test on the target battery itself instead of the secondary battery for measurement.

Further, after subjecting the target battery to a predetermined number of charge/discharge cycles during use, the load characteristics may be measured, and the data of these load characteristics obtained by the measurement may then be used to update the relationship between the number of cycles and the electrolyte diffusion coefficient, allowing for continuous correction of the prediction. In this case, only the load characteristics that can be measured in a short period of time, such as at 3 C and 5 C, may be acquired.

The number of cycles corresponding to the difference ΔD is obtained on the basis of the acquired relationship between the number of cycles and the electrolyte diffusion coefficient. More specifically, the number of cycles at which the difference ΔD becomes zero is obtained. The number of cycles No at which the difference ΔD becomes zero can be obtained by N₀=ΔD/k_{D} by using the slope k_{D} of the electrolyte diffusion coefficient with respect to the number of cycles. This makes it possible to predict the specific number of cycles at which the target battery becomes suitable for reuse.

### Fourth Embodiment

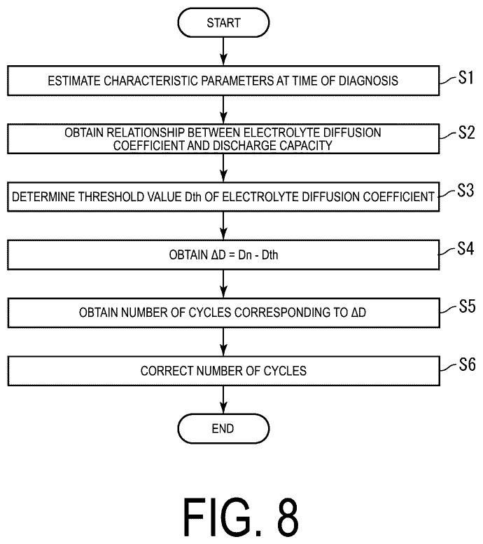

FIG. 8 is a flowchart of the secondary battery diagnostic method according to a fourth embodiment of the present invention. In addition to the processes included in the secondary battery diagnostic method according to the third embodiment (FIG. 7), this diagnostic method further includes a process of correcting the number of cycles on the basis of the relationship between the number of cycles and the threshold value of the electrolyte diffusion coefficient acquired in advance (step S6).

### Process of Correcting Number of Cycles

The number of cycles obtained in step S5 (number of cycles No corresponding to the difference ΔD) is corrected on the basis of the relationship between the number of cycles and the threshold value of the electrolyte diffusion coefficient acquired in advance (step S6). As described above, it has been experimentally revealed that the threshold value of the electrolyte diffusion coefficient changes substantially linearly with respect to the number of cycles. Taking this into consideration, by predicting the time point at which the electrolyte diffusion coefficient falls below the threshold value Dth, it is possible to predict, with higher accuracy, the specific number of cycles at which the target battery becomes unsuitable for reuse.

The relationship between the number of cycles and the threshold value Dth of the electrolyte diffusion coefficient can be acquired as follows, for example.

As when obtaining the relationship between the number of cycles and the electrolyte diffusion coefficient, a charge/discharge cycle test is conducted on the secondary battery for measurement under certain conditions to deteriorate the secondary battery for measurement. The load characteristics of the secondary battery for measurement are measured at two or more time points having different numbers of cycles, and the characteristic parameters of the secondary battery for measurement at each time point are estimated from the data of the load characteristics. As the data of the load characteristics and the characteristic parameters, those acquired when the relationship between the number of cycles and the electrolyte diffusion coefficient was obtained may be used.

The relationship between the electrolyte diffusion coefficient and the discharge capacity is obtained at each time point by using these characteristic parameters, and the threshold value of the electrolyte diffusion coefficient at each time point is then determined. These processes can be performed as in the process of obtaining the relationship between the electrolyte diffusion coefficient and the discharge capacity of the target battery (step S2) and the process of determining the threshold value Dth of the electrolyte diffusion coefficient of the target battery (step S3).

In a case in which the secondary battery undergoes cycle deterioration under certain conditions, the threshold value of the electrolyte diffusion coefficient changes substantially linearly with respect to the number of cycles. Therefore, if the threshold values of the electrolyte diffusion coefficient at at least two time points are known, the relationship between the number of cycles and the threshold value of the electrolyte diffusion coefficient can be acquired. For example, given Dth1 as the threshold value of the electrolyte diffusion coefficient when the number of cycles is n1 and Dth2 as the threshold value of the electrolyte diffusion coefficient when the number of cycles is n2, a slope kₜₕ of the threshold value of the electrolyte diffusion coefficient with respect to the number of cycles can be obtained by kₜₕ=(Dth2−Dth1)/(n2−n1). Needless to say, the threshold value of the electrolyte diffusion coefficient may be determined at three or more time points to obtain the slope kₜₕ, thereby further reducing errors.

As when obtaining the relationship between the number of cycles and the electrolyte diffusion coefficient, the relationship between the number of cycles and the threshold value of the electrolyte diffusion coefficient may be obtained by conducting a charge/discharge cycle test on the target battery itself instead of the secondary battery for measurement.

The number of cycles obtained in step S5 is corrected on the basis of the acquired relationship between the number of cycles and the threshold value of the electrolyte diffusion coefficient. In a case in which the electrolyte diffusion coefficient changes with the slope k_{D} with respect to the number of cycles, an electrolyte diffusion coefficient D′ after N cycles from the time of diagnosis is D′=Dn+k_{D}×N. Similarly, in a case in which the threshold value of the electrolyte diffusion coefficient changes with the slope kₜₕ with respect to the number of cycles, a threshold value Dth′ after N cycles from the time of diagnosis is Dth′=Dth+kₜₕ×N. The number of cycles N₁ at which D′ and Dth′ become equal can be obtained by N₁=(Dn−Dth)/(kₜₕ−k_{D}). This makes it possible to predict the specific number of cycles at which the target battery becomes unsuitable for reuse with higher accuracy.

### Fifth Embodiment (Method for Determining Threshold Value Dth and ΔD Using Learned Model)

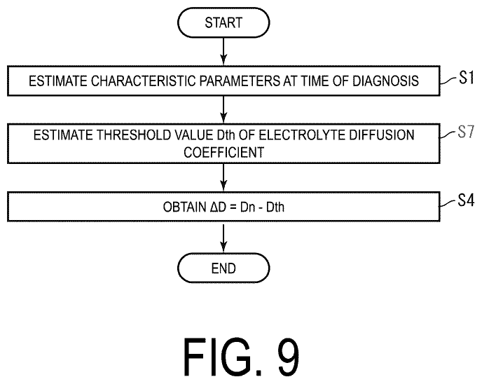

FIG. 9 is a flowchart of the secondary battery diagnostic method (when using a learned model) according to a fifth embodiment of the present invention. In this diagnostic method, the process of obtaining the relationship between the electrolyte diffusion coefficient and the discharge capacity (step S2) and the process of obtaining the threshold value Dth of the electrolyte diffusion coefficient (step S3) in FIG. 1 are replaced with a process of estimating the threshold value Dth of the electrolyte diffusion coefficient (step S7, hereinafter referred to as “threshold value estimation process”). The threshold value estimation process (step S7) is a process of estimating, on the basis of input data, the threshold value Dth of the electrolyte diffusion coefficient of the target battery by using a “learned model” described below, the input data being data including some of the characteristic parameters of the target battery at the time of diagnosis that are estimated in step S1.

### Learned Model

The learned model is an estimation model, input data (explanatory variables) and output data (objective variable) of which are respectively data including some of the characteristic parameters of the secondary battery and the threshold value of the electrolyte diffusion coefficient of the secondary battery, and the estimation model estimates the output data from the input data. The learned model is obtained by machine learning using teacher data created in advance using a plurality of secondary batteries (hereinafter referred to as “secondary batteries for learning”).

### Creation of Teacher Data

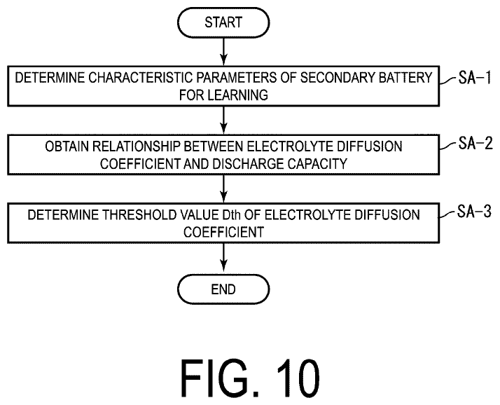

FIG. 10 is a flowchart illustrating an example of a method for creating the teacher data. This method for creating the teacher data includes a process of determining characteristic parameters of the secondary battery for learning (step SA-1), a process of obtaining a relationship between an electrolyte diffusion coefficient and a discharge capacity of the secondary battery for learning (step SA-2), and a process of determining a threshold value of the electrolyte diffusion coefficient of the secondary battery for learning (step SA-3).

The teacher data is preferably created for a plurality of secondary batteries having different types of active materials of the positive and negative electrodes, different usage conditions, different degrees of deterioration, and the like. The greater the number of secondary batteries for learning (that is, the more teacher data used for machine learning), the higher the accuracy of the resulting learned model.

The process of determining the characteristic parameters of the secondary battery for learning (step SA-1) is, more specifically, a process of estimating, on the basis of data obtained by measuring load characteristics of the actual battery, for example, the characteristic parameters of the actual battery by using a model equation. This estimation can be made in the same manner as in the process of estimating the characteristic parameters of the target battery at the time of diagnosis (step S1). Note that, in the process of determining the characteristic parameters of the secondary battery for learning (step SA-1), it is not necessary to analyze all target secondary batteries for learning using data (actual measurement data) obtained by measuring the load characteristics of each actual battery. For a secondary battery for learning similar to an actual battery already analyzed, the characteristic parameters may be determined on the basis of data obtained by the analysis of the actual battery (for example, by changing some of the characteristic parameters obtained by the analysis of the actual battery). However, for a secondary battery for learning having a significantly different shape or the like, preferably the characteristic parameters are estimated by analysis using actual measurement data.

The process of obtaining the relationship between the electrolyte diffusion coefficient and the discharge capacity of the secondary battery for learning (step SA-2) is, more specifically, a process of obtaining, on the basis of the model equation used in step SA-1 and the characteristic parameters of the secondary battery for learning determined in step SA-1, the discharge capacity when the electrolyte diffusion coefficient of the secondary battery for learning is changed, and obtaining the relationship between the electrolyte diffusion coefficient and the discharge capacity of the secondary battery for learning. The process of obtaining the relationship between the electrolyte diffusion coefficient and the discharge capacity of the secondary battery for learning (step SA-2) can be performed in the same manner as in the process of obtaining the relationship between the electrolyte diffusion coefficient and the discharge capacity of the target battery (step S2 in FIG. 1).

The process of determining the threshold value of the electrolyte diffusion coefficient of the secondary battery for learning (step SA-3), more specifically, is a process of determining, on the basis of the relationship between the electrolyte diffusion coefficient and the discharge capacity of the secondary battery for learning obtained in step SA-2, the threshold value of the electrolyte diffusion coefficient of the secondary battery for learning. The process of determining the threshold value of the electrolyte diffusion coefficient of the secondary battery for learning (step SA-3) can be performed in the same manner as in the process of determining the threshold value Dth of the electrolyte diffusion coefficient of the target battery (step S3 in FIG. 1).

The processes described above (step SA-1 to step SA-3) are performed for a plurality of the secondary batteries for learning to determine the threshold value of the electrolyte diffusion coefficient for each of the plurality of secondary batteries for learning. The teacher data is created by selecting, as input data (explanatory variables), several parameters selected from the parameters used in the process of obtaining the relationship between the electrolyte diffusion coefficient and the discharge capacity of the secondary battery for learning (step SA-2) and the like and using, as output data, the threshold value of the electrolyte diffusion coefficient.

The input data includes some of the characteristic parameters of the secondary battery for learning determined in step SA-1. The input data preferably includes the discharge capacity and the electrolyte conductivity of the secondary battery for learning. With these parameters included, the accuracy of the estimation can be further increased.

Note that, because the resistance of the electrolyte accounts for most of the ohmic resistance determined by impedance measurement of the secondary battery, the “ohmic resistance converted per electrode unit area” can be used instead of the electrolyte conductivity. While easy to acquire, ohmic resistance may be less accurate than using electrolyte conductivity since ohmic resistance includes the resistance of electrodes, the contact resistance of members such as tabs, and the like.

The input data preferably further includes a magnitude of the current (discharge rate) when the secondary battery is used. Here, the “magnitude of the current when the secondary battery is used” means the magnitude of the current when the secondary battery to be diagnosed is used after diagnosis. That is, the magnitude of the current when the secondary battery is used is not the value determined in step SA-1 (FIG. 10) or the value estimated in step S1 (FIG. 9), but a value determined by the application of the secondary battery to be diagnosed and the like.

The input data may further include a temperature when the secondary battery is used. Here, the “temperature when the secondary battery is used” means the temperature when the secondary battery to be diagnosed is used after diagnosis.

The input data preferably further includes one or two or more selected from the group consisting of an electrode area, a positive electrode application amount, a positive electrode active material type, a positive electrode porosity, a negative electrode porosity, and a heat capacity of the secondary battery for learning. These parameters are all relatively easy to acquire and have a relatively large influence on the accuracy of the estimation.

Among the parameters mentioned above, the electrode area, the positive electrode application amount, and the positive electrode active material type do not change with use, and thus the data at the time of manufacture of new batteries can be used. For the positive electrode porosity and negative electrode porosity, the data at the time of manufacture of new batteries can be used. Alternatively, because a typical expansion amount is generally known according to the type of active material, a maximum value expected after deterioration may be used. The heat capacity of the secondary battery can be estimated in step SA-1, for example. Note that, with the heat capacity being the same if the type is the same, the estimation of the heat capacity may be performed only once for secondary batteries of the same type and may be treated as a constant thereafter.

The input data may include, in addition to the aforementioned, a positive electrode active material capacity, a positive electrode active material in-solid phase diffusion coefficient, a negative electrode active material capacity, a negative electrode utilization rate, a negative electrode active material in-solid phase diffusion coefficient, a separator thickness, and the like.

### Generation of Learned Model

The estimation model (learned model) for estimating the output data (objective variable) from input data (explanatory variables) is generated by machine learning by using the generated teacher data. An algorithm of the machine learning is not particularly limited. For example, nonlinear support vector regression can be used.

In the secondary battery diagnostic method (FIG. 9) according to the present embodiment, the threshold value Dth of the electrolyte diffusion coefficient of the target battery is estimated on the basis of the input data by using this learned model, the input data being data including some of the characteristic parameters of the target battery at the time of diagnosis that are estimated in step S1 (step S7).

The input data used in the threshold value estimation process (step S7) is input data corresponding to the input data used in the machine learning. For example, when the discharge capacity and the electrolyte conductivity of the secondary battery for learning are used as the input data in the machine learning, the discharge capacity and the electrolyte conductivity of the target battery are used as the input data in the threshold value estimation step.

According to the present embodiment, once the learned model is generated, the process of obtaining the relationship between the electrolyte diffusion coefficient and the discharge capacity (step S2 in FIG. 1) does not need to be performed each time a diagnosis is performed, making it possible to evaluate the remaining life of the secondary battery more easily.

### Secondary Battery Diagnostic Program and the Like

The secondary battery diagnostic method described above can also be realized as a computer program. A secondary battery diagnostic program according to an embodiment of the present invention is a secondary battery diagnostic program for causing a computer to execute estimating, on the basis of data obtained by measuring load characteristics of a secondary battery to be diagnosed, characteristic parameters of the secondary battery to be diagnosed at a time of diagnosis by using a predetermined model equation, the characteristic parameters including the electrolyte diffusion coefficient Dn of the secondary battery to be diagnosed at the time of diagnosis; obtaining, on the basis of the model equation and the characteristic parameters estimated, a discharge capacity when an electrolyte diffusion coefficient is changed, and obtaining a relationship between the electrolyte diffusion coefficient and the discharge capacity; determining, on the basis of the relationship between the electrolyte diffusion coefficient and the discharge capacity, the threshold value Dth of the electrolyte diffusion coefficient; and obtaining the difference ΔD between the threshold value Dth and the electrolyte diffusion coefficient Dn at the time of diagnosis. According to the present embodiment as well, it is possible to more accurately evaluate the remaining life of the target battery as compared with known methods in which the remaining life is evaluated on the basis of the magnitude of the discharge capacity at the time of diagnosis.

The computer program of a form corresponding to the secondary battery diagnostic method according to the first embodiment has been described above. However, the secondary battery diagnostic methods according to the second to fifth embodiments can also be realized as computer programs.

That is, a secondary battery diagnostic program according to an embodiment of the present invention may be a secondary battery diagnostic program for causing a computer to execute estimating, on the basis of data obtained by measuring load characteristics of a secondary battery to be diagnosed, characteristic parameters of the secondary battery to be diagnosed at a time of diagnosis by using a predetermined model equation, the characteristic parameters including the electrolyte diffusion coefficient Dn of the secondary battery to be diagnosed at the time of diagnosis; estimating, on the basis of input data, the threshold value Dth of the electrolyte diffusion coefficient of the secondary battery to be diagnosed by using a learned model, the input data being data including some of the characteristic parameters at the time of diagnosis; and obtaining the difference ΔD between the threshold value Dth and the electrolyte diffusion coefficient Dn at the time of diagnosis. According to the present embodiment as well, it is possible to more accurately evaluate the remaining life of the target battery as compared with known methods in which the remaining life is evaluated on the basis of the magnitude of the discharge capacity at the time of diagnosis.

The secondary battery electrode diagnostic methods described above can also be realized as computer-readable recording media in which the computer program described above is recorded.

The secondary battery diagnostic methods described above can also be realized as computer systems. A secondary battery diagnostic system according to an embodiment of the present invention includes a memory and a processor, and the processor, according to a program in the memory, executes estimating, on the basis of data obtained by measuring load characteristics of a secondary battery to be diagnosed, characteristic parameters of the secondary battery to be diagnosed at a time of diagnosis by using a predetermined model equation, the characteristic parameters including the electrolyte diffusion coefficient Dn of the secondary battery to be diagnosed at the time of diagnosis; obtaining, on the basis of the model equation and the characteristic parameters estimated, a discharge capacity when an electrolyte diffusion coefficient is changed, and obtaining a relationship between the electrolyte diffusion coefficient and the discharge capacity; determining, on the basis of the relationship between the electrolyte diffusion coefficient and the discharge capacity, the threshold value Dth of the electrolyte diffusion coefficient; and obtaining the difference ΔD between the threshold value Dth and the electrolyte diffusion coefficient Dn at the time of diagnosis.

A secondary battery diagnostic system according to an embodiment of the present invention may include a memory and a processor, and the processor, according to a program in the memory, may execute estimating, on the basis of data obtained by measuring load characteristics of a secondary battery to be diagnosed, characteristic parameters of the secondary battery to be diagnosed at a time of diagnosis by using a predetermined model equation, the characteristic parameters including the electrolyte diffusion coefficient Dn of the secondary battery to be diagnosed at the time of diagnosis; estimating, on the basis of input data, the threshold value Dth of the electrolyte diffusion coefficient of the secondary battery to be diagnosed by using a learned model, the input data being data including some of the characteristic parameters at the time of diagnosis; and obtaining the difference ΔD between the threshold value Dth and the electrolyte diffusion coefficient Dn at the time of diagnosis.

### Secondary Battery Diagnostic Apparatus

A secondary battery diagnostic apparatus according to an embodiment of the present invention includes a parameter estimation device configured to estimate, on the basis of data obtained by measuring load characteristics of a secondary battery to be diagnosed, characteristic parameters of the secondary battery to be diagnosed at a time of diagnosis by using a predetermined model equation, the characteristic parameters including the electrolyte diffusion coefficient Dn of the secondary battery to be diagnosed at the time of diagnosis; a threshold value estimation device configured to estimate, on the basis of input data, the threshold value Dth of the electrolyte diffusion coefficient of the secondary battery to be diagnosed by using a learned model, the input data being data including some of the characteristic parameters at the time of diagnosis; and a difference calculation device configured to obtain the difference ΔD between the threshold value Dth and the electrolyte diffusion coefficient Dn at the time of diagnosis.

A secondary battery diagnostic apparatus according to another embodiment of the present invention includes a parameter estimation device configured to estimate, on the basis of data obtained by measuring load characteristics of a secondary battery to be diagnosed, characteristic parameters of the secondary battery to be diagnosed at a time of diagnosis by using a predetermined model equation, the characteristic parameters including an electrolyte diffusion coefficient Dn of the secondary battery to be diagnosed at the time of diagnosis; a first data generation device configured to determine, for each of a plurality of secondary batteries for learning, characteristic parameters of the secondary battery for learning; a second data generation device configured to obtain, on the basis of the model equation and the characteristic parameters of the secondary battery for learning, a discharge capacity when an electrolyte diffusion coefficient of the secondary battery for learning is changed, and obtain a relationship between the electrolyte diffusion coefficient and the discharge capacity of the secondary battery for learning; a third data generation device configured to determine, on the basis of the relationship between the electrolyte diffusion coefficient and the discharge capacity of the secondary battery for learning, a threshold value of the electrolyte diffusion coefficient of the secondary battery for learning; a model generation device configured to generate a learned model by machine learning utilizing teacher data obtained by using, as input data, data including some of the characteristic parameters of the secondary batteries for learning and, as output data, the threshold values determined for the electrolyte diffusion coefficients of the secondary batteries; a threshold value estimation device configured to estimate, on the basis of input data, a threshold value Dth of the electrolyte diffusion coefficient of the secondary battery to be diagnosed by using the learned model, the input data being data including some of the characteristic parameters at the time of diagnosis; and a difference calculation device configured to obtain a difference ΔD between the threshold value Dth and the electrolyte diffusion coefficient Dn at the time of diagnosis.

According to these embodiment as well, it is possible to more accurately evaluate the remaining life of the target battery as compared with known methods in which the remaining life is evaluated on the basis of the magnitude of the discharge capacity at the time of diagnosis.

### EXAMPLES

Hereinafter, the present invention will be described more specifically with reference to examples. The present invention is not limited to these examples.

A plurality of medium-sized laminate-type cells having a rated capacity of 5 Ah and a plurality of small-sized laminate-type cells having a rated capacity of 36 mAh were fabricated.

### Medium-Sized Laminate-Type Cell

### Fabrication of Positive Electrode

A positive-electrode-mixture-containing slurry was prepared by uniformly mixing 93 parts by mass of LiCoO₂ as a positive electrode active material, 3 parts by mass of carbon black as a conductive aid, and 4 parts by mass of polyvinylidene fluoride (PVDF) as a binder, using N-methyl-2-pyrrolidone (NMP) as a solvent. This positive-electrode-mixture-containing slurry was applied to both sides of a positive electrode current collector made of aluminum foil having a thickness of 15 μm, dried, subsequently pressure-formed using a roller press machine, and then punched out so that a portion of the positive electrode current collector not coated with the positive-electrode-mixture-containing slurry became a tab portion, thereby fabricating the positive electrode.

### Fabrication of Negative Electrode

A negative-electrode-mixture-containing slurry was prepared by mixing 97.5 parts by mass of graphite as a negative electrode active material, 1.5 parts by mass of carboxymethyl cellulose as a binder, and 1 part by mass of styrene-butadiene rubber, and then adding an appropriate amount of water and thoroughly mixing. This negative-electrode-mixture-containing slurry was applied to both sides of a negative electrode current collector made of copper foil having a thickness of 10 μm, dried, subsequently pressure-formed using a roller press machine, and then punched out so that a portion of the negative electrode current collector not coated with the negative-electrode-mixture-containing slurry became a tab portion, thereby fabricating the negative electrode.

### Fabrication of Battery

Seven of the positive electrodes described above and eight of the negative electrodes described above were alternately layered with a polyolefin microporous film separator interposed therebetween to form a multilayer electrode body, the polyolefin microporous film separator having a thickness of 18 μm and a three-layer structure consisting of a polyethylene layer as a middle layer and two polypropylene layers as outer layers.

Next, the tab portions of the positive electrodes of the multilayer electrode body were welded together and the tab portions of the negative electrodes of the multilayer electrode body were welded together and leads were connected respectively thereto. Then, the multilayer electrode body was enclosed inside an outer packaging made from an aluminum laminate film together with a non-aqueous electrolyte prepared by dissolving LiPF₆ at a concentration of 1 mol/L in a solution obtained by mixing ethylene carbonate, diethyl carbonate, and methyl ethyl carbonate at a volume ratio of 1:1:1, and further dissolving vinylene carbonate in an amount of 1 mass %, thereby fabricating a non-aqueous electrolyte secondary battery with a rated capacity of 5 Ah.

### Small-Sized Laminate-Type Cell

### Fabrication of Positive Electrode

A positive-electrode-mixture-containing slurry was prepared by uniformly mixing 94 parts by mass of LiCoO₂ as the positive electrode active material, 4 parts by mass of carbon black as the conductive aid, and 2 parts by mass of PVDF as the binder, using NMP as the solvent. This positive-electrode-mixture-containing slurry was applied to both sides of a positive electrode current collector made of aluminum foil having a thickness of 15 μm, dried, subsequently pressure-formed using a roller press machine, and then punched out so that a portion of the positive electrode current collector not coated with the positive-electrode-mixture-containing slurry became a tab portion, thereby fabricating the positive electrode.

### Fabrication of Negative Electrode

A negative-electrode-mixture-containing slurry was prepared by mixing 94.5 parts by mass of graphite and 3 parts by mass of SiO particles (D50: 5.0 μm) including a front surface coated with carbon as the negative electrode active material, 1.5 parts by mass of carboxymethyl cellulose and 1 part by mass of styrene-butadiene rubber as the binder, and then adding an appropriate amount of water and thoroughly mixing. This negative-electrode-mixture-containing slurry was applied to both sides of a negative electrode current collector made of copper foil having a thickness of 10 μm, dried, subsequently pressure-formed using a roller press machine, and then punched out so that a portion of the negative electrode current collector not coated with the negative-electrode-mixture-containing slurry became a tab portion, thereby fabricating the negative electrode.

### Fabrication of Battery

The positive electrode described above and the negative electrode described above were layered with a polyolefin microporous film separator interposed therebetween to form a multilayer electrode body, the polyolefin microporous film separator having a thickness of 12 μm and a three-layer structure consisting of a polyethylene layer as the middle layer and two polypropylene layers as the outer layers.

Next, leads were respectively connected to the tab portion of the positive electrode and the tab portion of the negative electrode of the multilayer electrode body. Then, the multilayer electrode body was enclosed inside an outer packaging made from an aluminum laminate film together with a non-aqueous electrolyte prepared by dissolving LiPF₆ at a concentration of 1 mol/L in a solution obtained by mixing ethylene carbonate and diethyl carbonate at a volume ratio of 3:7, and further dissolving vinylene carbonate in an amount of 1 mass %, thereby fabricating a non-aqueous electrolyte secondary battery with a rated capacity of 36 mAh.

### Fabrication of Deteriorated Cells

A plurality of deteriorated cells having discharge capacities reduced to 4.8 Ah were fabricated by conducting charge/discharge cycle tests on the medium-sized laminate-type cells having a rated capacity of 5 Ah under a plurality of conditions different in terms of charge/discharge rate, ambient temperature, and the like. Similarly, a plurality of deteriorated cells having discharge capacities reduced to 35 mAh were fabricated by conducting charge/discharge cycle tests on the small-sized laminate-type cells having a rated capacity of 36 mAh under a plurality of conditions different in charge/discharge rate, ambient temperature, and the like.

### Measurement of Load Characteristics

The load characteristics of these deteriorated cells were measured. Specifically, discharge curves were measured at discharge rates of 0.02 C, 0.2 C, 0.5 C, and 1 C.

### Diagnosis of Secondary Battery

The secondary battery diagnostic method described in the embodiment was carried out using these deteriorated cells as target batteries. The analysis (simulation) was carried out by the software Battery Design Studio available from Siemens AG. Among the basic specifications, a solvent ratio and a salt concentration were input using the same values as those at the time of fabrication (because the values at the time of diagnosis cannot be measured).

The relationship between the electrolyte diffusion coefficient and the discharge capacity was acquired by estimating the characteristic parameters at the time of diagnosis and subsequently, on the basis of the estimated characteristic parameters, obtaining the discharge capacity at an ambient temperature of 45° C. and a discharge rate of 0.5 C while changing the electrolyte diffusion coefficient. The difference ΔD between the threshold value Dth and the electrolyte diffusion coefficient Dn at the time of diagnosis was obtained with the point at which tangents of each curve before and after the onset of a sharp drop in discharge capacity intersect defined as the threshold value Dth.

### Measurement of Remaining Life

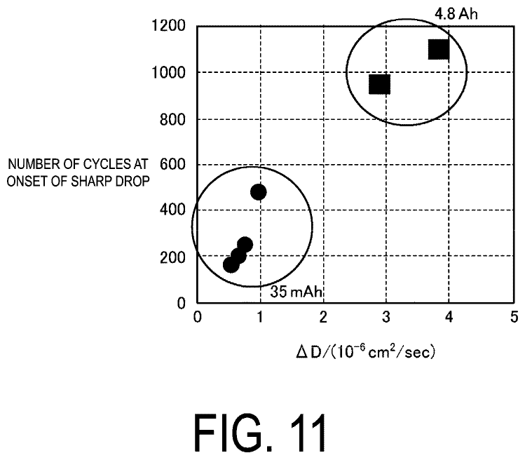

These deteriorated cells were subjected to charge/discharge cycle tests under the same conditions, and the number of charge/discharge cycles until a sharp drop in discharge capacity occurred (number of cycles at the onset of a sharp drop) was measured. FIG. 11 shows the relationship between ΔD obtained by the diagnosis and the number of cycles at the onset of a sharp drop. Note that FIG. 11 excludes the data of a cell in which Li deposition described below occurred in the charge/discharge cycle test.

As shown in FIG. 11, even when the discharge capacities at the time of diagnosis were equivalent (4.8 Ah or 35 mAh), a difference in ΔD was confirmed. Further, the number of cycles at the onset of a sharp drop was found to also change in accordance with ΔD, confirming the validity of this diagnostic method.

### Setting of Threshold Value Dth Using Equation (1)

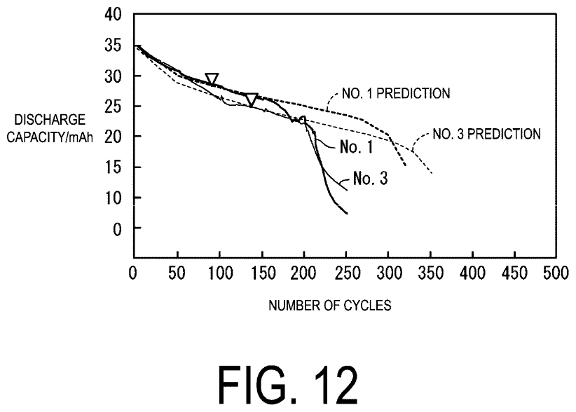

FIG. 12 is a graph illustrating the relationship between the number of cycles and the discharge capacity of two cells (Cell No. 1 and Cell No. 3) in which Li deposition occurred. The solid line represents actual measurement data, and the dashed line represents predicted values by simulation.

Specifically, the predicted values by simulation were calculated as follows.

The load characteristics of the deteriorated cell were measured during the charge/discharge cycle test, and an electrolyte diffusion coefficient Dm during the charge/discharge cycle test was estimated by the same method as that for estimating Dn. Under the assumption that the electrolyte diffusion coefficient linearly decreases with respect to the number of cycles, the electrolyte diffusion coefficient DN after N cycles was expressed by equation (2) below. The value of DN obtained from equation (2) was substituted for D in equation (1) to obtain the discharge capacity C(N) after N cycles. The discharge capacity C(N) after N cycles was divided by the initial discharge capacity C(0) to obtain a capacity retention rate q(N)=C(N)/C(0) after N cycles.

$$DN = ( Dm - Dn ) / m \times N + Dn \qquad ( 2 )$$

Here, m is the number of cycles when Dm is estimated.

In the case of cycle deterioration, in addition to a decrease in discharge capacity due to a decrease in liquid diffusivity, a decrease in discharge capacity in accordance with the root law occurs as steady deterioration. Of the actual measurement data, data before a sharp drop in discharge capacity occurred was fitted with equation (3) below to obtain a discharge capacity R(N) after N cycles in accordance with the root law. The predicted value from the simulation was obtained by multiplying this discharge capacity R(N) by the capacity retention rate q(N) described above.

$$R ( N ) = C ( 0 ) - r \times {N}^{1 / 2} \qquad ( 3 )$$

Here, r is a parameter obtained by fitting.

The predicted value by simulation corresponds to a change in discharge capacity in a case in which Li deposition does not occur. In the actual measurement data, due to Li deposition, a sharp drop in discharge capacity occurs at a time point earlier than the predicted value.

The triangular mark in FIG. 12 indicates a time point at which the electrolyte diffusion coefficient becomes 56% of Dh. In the actual measurement data, shortly after the time point when the electrolyte diffusion coefficient reaches 56% of the value of Dh, the discharge capacity becomes unstable, and Li deposition begins to occur.

Cells in which Li deposition does not occur can be used for a longer period. However, taking into consideration the likelihood of Li deposition, it can be said that the threshold value Dth of the electrolyte diffusion coefficient is desirably set to a value of from 50% to 60% of Dh.

Relationship between Number of Cycles and Electrolyte Diffusion Coefficient

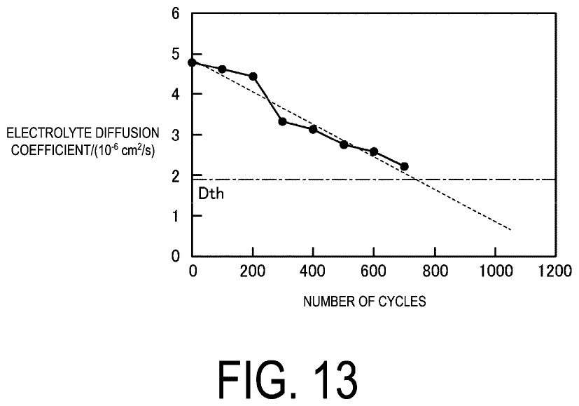

For deteriorated cells having a discharge capacity of 4.8 Ah, the load characteristics were measured every 100 cycles during the charge/discharge cycle test, and the electrolyte diffusion coefficient at each time point was estimated by using the same method as that used to estimate Dn. FIG. 13 is a graph showing the relationship between the number of cycles and the electrolyte diffusion coefficient. The alternate long and short dashed line indicates the threshold value Dth of the electrolyte diffusion coefficient.

As shown in FIG. 13, it can be seen that the electrolyte diffusion coefficient decreases substantially linearly with respect to the number of cycles. Furthermore, in FIG. 13, at the time point of 700 cycles, ΔD is only 0.3×10⁻⁶ cm²/s and, when the change in the electrolyte diffusion coefficient is subsequently extrapolated, it is possible to predict the onset of a sharp drop, that is, the onset of deviation from the root law, around approximately 800 cycles.

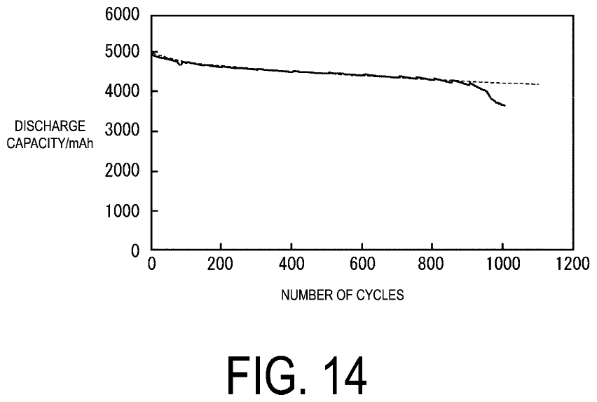

FIG. 14 is a graph showing the results of the cycle test of the deteriorated cell used for estimation in FIG. 13. The solid line is the actual measurement value, and the dashed line is a line showing a cycle curve based on the root law. As shown in FIG. 14, it was confirmed that the onset of deviation from the root law occurred after about 900 cycles and, although there was a slight prediction error, a sharp drop actually occurred.

In the related art, a method for predicting the “sharp drop” deviating from the root law in terms of the “number” of cycles is nonexistent, making this technique a completely novel technique. Furthermore, the predicted number of cycles deviates only by about 100 cycles from the final life of approximately 1000 cycles, indicating that the prediction is generally valid.

Relationship between Number of Cycles and Threshold Value of Electrolyte Diffusion Coefficient

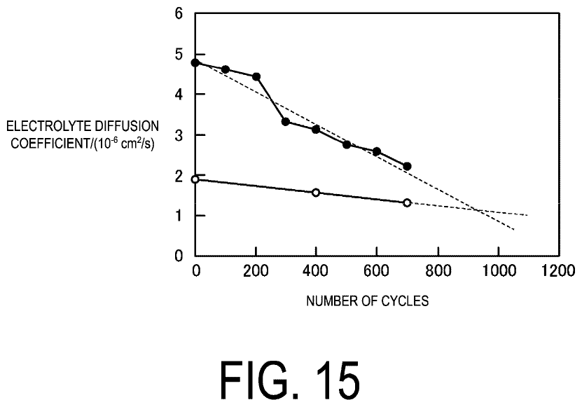

Next, the relationship between the electrolyte diffusion coefficient and the discharge capacity was obtained from the characteristic parameters estimated at 400 cycles and at 700 cycles, and the threshold value of the electrolyte diffusion coefficient was obtained at 400 cycles and at 700 cycles. FIG. 15 is a graph obtained by adding the relationship between the number of cycles and the threshold value of the electrolyte diffusion coefficient to the graph of FIG. 13. The unfilled marks in the graph are the threshold values of the electrolyte diffusion coefficient.

As shown in FIG. 15, it can be seen that the threshold value of the electrolyte diffusion coefficient also decreases substantially linearly with respect to the number of cycles, as with the electrolyte diffusion coefficient. It can be predicted that the line obtained by extrapolating the change in the electrolyte diffusion coefficient and the line obtained by extrapolating the change in the threshold value of the electrolyte diffusion coefficient will intersect at the time point of approximately 900 cycles. This is in favorable agreement with the number of cycles at the onset of deviation from the root law in FIG. 14. These prediction results were found to reproduce the actually measured cycle capacity decrease with great accuracy and found to be valid.

### Generation of Learned Model

Next, secondary batteries using lithium cobalt oxide (LCO) or lithium nickel cobalt manganese oxide (NCM) as a positive electrode active material and graphite or SiO as a negative electrode active material were prepared. The load characteristics of these secondary batteries were measured, and the threshold values of the electrolyte diffusion coefficients were obtained by the method described above. Machine learning was performed using this data as teacher data (however, some data was used not as teacher data (training data) but as verification data (validation data)) to generate a learned model.

As input data (explanatory variables), the nine variables below were used.
1. Discharge capacity
2. Electrode area
3. Magnitude of current when secondary battery is used
4. Positive electrode application amount
5. Positive electrode active material type
6. Positive electrode porosity
7. Negative electrode porosity
8. Electrolyte conductivity

9. Heat capacity of secondary battery

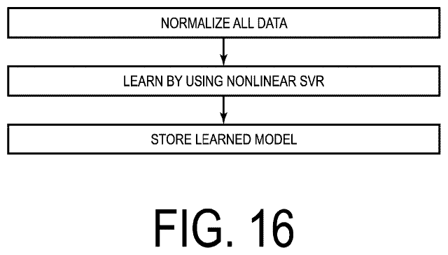

The machine learning was performed using scikit-learn, an open source library. FIG. 16 illustrates the procedure of the machine learning. As the algorithm for machine learning, nonlinear support vector regression (nonlinear SVR) was used.

First, all data were normalized by the equation below.

$$Xn = ( X - Xa ) / Xd$$

X: Original value, Xn: Value after normalization, Xa: Average value of variable X, Xd: Standard deviation

In the non-linear SVR, a weighting coefficient w was obtained, minimizing the function below.

$$\frac{1}{2} {‖ w ‖}^{2} + C {\sum }_{i = 1}^{n} h ( {y}^{( i )} - f ( {x}^{( i )} ) ) \qquad Equation 1$$

$$f ( {x}^{( i )} ) = ϕ ( {x}^{( i )} ) w + c$$

Φ(x): Parameter after nonlinear mapping of original x, w: Weighting coefficient of each parameter, c: Constant, y: Target variable (threshold value of electrolyte diffusion coefficient)

h(y⁽ⁱ⁾−f(x⁽ⁱ⁾)) is a function represented by the equation below.

$$h ( {y}^{( i )} - f ( {x}^{( i )} ) = max ( 0 , \vert {y}^{( i )} - f ( {x}^{( i )} ) \vert - ε )$$

C and ε are so-called hyperparameters.

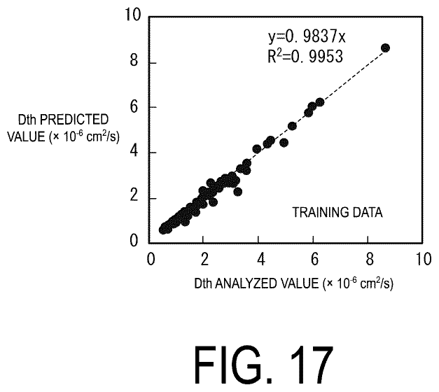

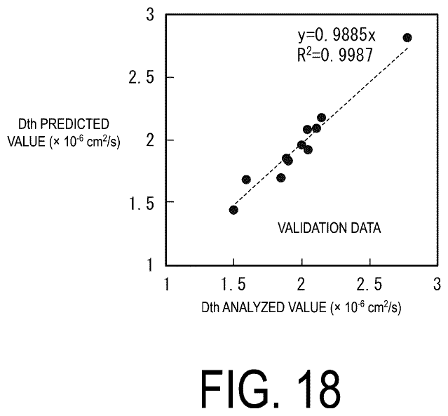

FIG. 17 and FIG. 18 are scatter diagrams obtained by plotting predicted values of the threshold value of the electrolyte diffusion coefficient on the vertical axis and plotting true values (values obtained by analysis) on the horizontal axis. FIG. 17 is a diagram corresponding to the training data (100 data used) and FIG. 18 is a diagram corresponding to the validation data (data not used for learning). As shown in FIG. 18, the values obtained by analysis can be predicted with favorable accuracy even for non-learning data.

### Contribution of Electrolyte Conductivity to Dth

The influence of electrolyte conductivity on Dth was studied using a learned model.

For a certain secondary battery, when the electrolyte conductivity was decreased from 8.90 (mS/cm) to 1.75 (mS/cm) without changing other parameters, Dth increased from 2.705×10⁻⁶ (cm²/s) to 2.758×10⁻⁶ (cm²/s).

For the same secondary battery, when the heat capacity was halved without changing the electrolyte conductivity, Dth decreased from 2.705×10⁻⁶ (cm²/s) to 2.643×10⁻⁶ (cm²/s).

Next, a case in which the heat capacity is halved and the electrolyte conductivity is reduced to 1.75 (mS/cm) will be considered. From the results described above, it is expected that Dth will be 2.643×10⁻⁶ (cm²/s) by halving the heat capacity, and then will increase by reducing the electrolyte conductivity. However, according to the results of the learned model, the Dth decreased from 2.643×10⁻⁶ (cm²/s) to 2.575×10⁻⁶ (cm²/s).

Thus, depending on the amount of change in other parameters, the influence of the electrolyte conductivity on Dth is not constant, and a correlation between parameters exists. This reveals that simple prediction is difficult.

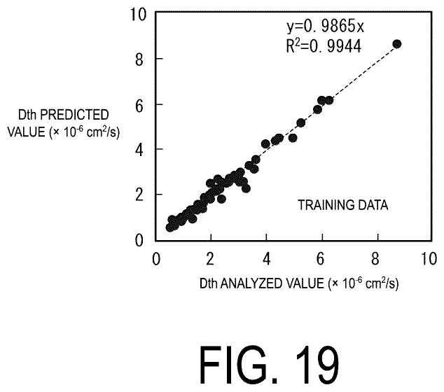

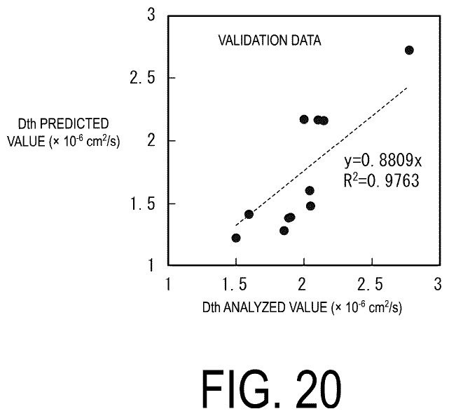

For comparison, machine learning was performed by removing the electrolyte conductivity from the input data (explanatory variables), and a learned model was created. FIG. 19 and FIG. 20 are scatter diagrams obtained by plotting predicted values of the threshold value of the electrolyte diffusion coefficient on the vertical axis and plotting true values (values obtained by analysis) on the horizontal axis. FIG. 19 is a diagram corresponding to training data, and FIG. 20 is a diagram corresponding to validation data (data not used for learning). As shown in FIG. 20, in this learned model, the accuracy of prediction was inferior as compared with the result of the learned model in which the electrolyte conductivity was included in the input data (FIG. 18).

From this, it is understood that the accuracy of prediction can be improved by including the electrolyte conductivity in the input data.

Although embodiments of the present invention have been described above, the present invention is not limited to the above-described embodiments, and various modifications can be made within the scope of the invention. For example, although a case in which the secondary battery is a single battery has been described in the embodiments above, in a case in which the secondary battery is a battery pack, not only can the present invention be applied to the individual batteries, but the present invention can be applied to the battery pack with the entire battery pack regarded as one battery.

1. A secondary battery diagnostic method comprising:
estimating, on the basis of data obtained by measuring load characteristics of a secondary battery to be diagnosed, characteristic parameters of the secondary battery to be diagnosed at a time of diagnosis by using a predetermined model equation, the characteristic parameters including an electrolyte diffusion coefficient Dn of the secondary battery to be diagnosed at the time of diagnosis;
obtaining, on the basis of the model equation and the characteristic parameters estimated, a discharge capacity when an electrolyte diffusion coefficient is changed, and obtaining a relationship between the electrolyte diffusion coefficient and the discharge capacity;
determining, on the basis of the relationship between the electrolyte diffusion coefficient and the discharge capacity, a threshold value Dth of the electrolyte diffusion coefficient; and
obtaining a difference ΔD between the threshold value Dth and the electrolyte diffusion coefficient Dn at the time of diagnosis.

2. The secondary battery diagnostic method according to claim 1, wherein
in the determination of the threshold value Dth, an electrolyte diffusion coefficient when the discharge capacity is a predetermined permissible value or less is determined to be the threshold value Dth.

3. The secondary battery diagnostic method according to claim 1, wherein
in the determination of the threshold value Dth, an electrolyte diffusion coefficient at the onset of a sharp drop in the discharge capacity is determined to be the threshold value Dth.

4. The secondary battery diagnostic method according to claim 1, wherein
the determination of the threshold value Dth includes obtaining Amax, B, and Dh by fitting the relationship between the electrolyte diffusion coefficient D and the discharge capacity with equation (1) below, and
determining the threshold value Dth on the basis of the Dh
Discharge capacity=A max−B×EXP(Dh/D) (1).

5. The secondary battery diagnostic method according to claim 1, further comprising:
predicting, on the basis of a relationship between the difference ΔD and a remaining life measured in advance, a remaining life of the secondary battery to be diagnosed.

6. The secondary battery diagnostic method according to claim 1, further comprising:
obtaining, on the basis of a relationship between the number of cycles and the electrolyte diffusion coefficient acquired in advance, the number of cycles corresponding to the difference ΔD.

7. The secondary battery diagnostic method according to claim 6, wherein
the number of cycles corresponding to the difference ΔD is obtained by approximating the relationship between the number of cycles and the electrolyte diffusion coefficient by a straight line.

8. The secondary battery diagnostic method according to claim 6, wherein
the relationship between the number of cycles and the electrolyte diffusion coefficient is acquired from data obtained for the secondary battery to be diagnosed or a secondary battery of an identical type to the secondary battery to be diagnosed.

9. The secondary battery diagnostic method according to claim 6, further comprising:
correcting the number of cycles corresponding to the difference ΔD on the basis of a relationship between the number of cycles and a threshold value of the electrolyte diffusion coefficient acquired in advance.

10. The secondary battery diagnostic method according to claim 9, wherein
the number of cycles corresponding to the difference ΔD is corrected by approximating the relationship between the number of cycles and the threshold value of the electrolyte diffusion coefficient by a straight line.

11. The secondary battery diagnostic method according to claim 1, wherein
the data obtained by measuring the load characteristics includes a discharge curve obtained by measuring the secondary battery to be diagnosed at a plurality of discharge rates.

12. The secondary battery diagnostic method according to claim 1, wherein
the secondary battery to be diagnosed is a lithium ion battery.

13. A secondary battery diagnostic method comprising:
estimating, on the basis of data obtained by measuring load characteristics of a secondary battery to be diagnosed, characteristic parameters of the secondary battery to be diagnosed at a time of diagnosis by using a predetermined model equation, the characteristic parameters including an electrolyte diffusion coefficient Dn of the secondary battery to be diagnosed at the time of diagnosis;
estimating, on the basis of input data, a threshold value Dth of the electrolyte diffusion coefficient of the secondary battery to be diagnosed by using a learned model, the input data being data including some of the characteristic parameters at the time of diagnosis; and
obtaining a difference ΔD between the threshold value Dth and the electrolyte diffusion coefficient Dn at the time of diagnosis, wherein
for each of a plurality of secondary batteries for learning, the following process is performed:
determining characteristic parameters of the secondary battery for learning;
obtaining, on the basis of the model equation and the characteristic parameters of the secondary battery for learning, a discharge capacity when an electrolyte diffusion coefficient of the secondary battery for learning is changed, and obtaining a relationship between the electrolyte diffusion coefficient and the discharge capacity of the secondary battery for learning; and
determining, on the basis of the relationship between the electrolyte diffusion coefficient and the discharge capacity of the secondary battery for learning, a threshold value of the electrolyte diffusion coefficient of the secondary battery for learning, and
the learned model is generated by machine learning utilizing teacher data obtained by using, as input data, data including some of the characteristic parameters of the secondary batteries for learning and, as output data, the threshold values of the electrolyte diffusion coefficients of the secondary batteries determined.

14. The secondary battery diagnostic method according to claim 13, wherein
the input data used in the machine learning includes the discharge capacity and an electrolyte conductivity or an ohmic resistance converted per electrode unit area of the secondary battery for leaning, and
the input data used in the estimation of the threshold value includes a discharge capacity and an electrolyte conductivity or an ohmic resistance converted per electrode unit area of the secondary battery to be diagnosed at the time of diagnosis.

15. The secondary battery diagnostic method according to claim 14, wherein
the input data used in the machine learning and the estimation of the threshold value further includes a magnitude of a current when the secondary battery is used.

16. The secondary battery diagnostic method according to claim 14, wherein
the input data used in the machine learning further includes one or two or more selected from the group consisting of an electrode area, a positive electrode application amount, a positive electrode active material type, a positive electrode porosity, a negative electrode porosity, and a heat capacity of the secondary battery for learning, and
the input data used in the estimation of the threshold value further includes one or two or more selected from the group consisting of an electrode area, a positive electrode application amount, a positive electrode active material type, a positive electrode porosity, a negative electrode porosity, and a heat capacity of the secondary battery to be diagnosed.

17. The secondary battery diagnostic method according to claim 13, wherein
in the determination of the threshold value of the electrolyte diffusion coefficient of the secondary battery for learning, an electrolyte diffusion coefficient when the discharge capacity is a predetermined permissible value or less is determined to be the threshold value.

18. The secondary battery diagnostic method according to claim 13, wherein
in the determination of the threshold value of the electrolyte diffusion coefficient of the secondary battery for learning, an electrolyte diffusion coefficient at the onset of a sharp drop in the discharge capacity is determined to be the threshold value.

19. The secondary battery diagnostic method according to claim 13, wherein
the data obtained by measuring the load characteristics includes a discharge curve obtained by measuring the secondary battery to be diagnosed at a plurality of discharge rates.

20. The secondary battery diagnostic method according to claim 13, wherein
the secondary battery to be diagnosed and the plurality of secondary batteries for learning are each a lithium ion battery.
